(19) United States
(12) Patent Application Publication
(10) Pub. No.: US 2012/0318962 A1
(43) Pub. Date: Dec. 20, 2012

(54) BACKSIDE ILLUMINATION SOLID-STATE IMAGE PICKUP DEVICE

(76) Inventors: Ikuko INOUE, Yokohama-shi (JP); Hajime OOTAKE, Kawasaki-shi (JP); Hiromichi SEKI, Oita-shi (JP)

(21) Appl. No.: 13/527,935

(22) Filed: Jun. 20, 2012

(30) Foreign Application Priority Data
Jun. 20, 2011 (JP) 2011-136353

(51) Int. Cl. H01L 27/146; H01L 31/18

(52) U.S. Cl. 250/208.1; 438/70; 257/E31.127

(57) ABSTRACT

According to one embodiment, an image pickup device includes a semiconductor substrate and first and second color filters. The semiconductor substrate includes a first principal surface and a second principal surface lying opposite the first principal surface. The first color filter has a first bottom surface lying on the second principal surface side and a first top surface lying opposite the first bottom surface. The second color filter has a second bottom surface lying on the second principal surface side and a second top surface lying opposite the second bottom surface. The first color filter includes a spectroscopic filter configured to allow light having passed through the semiconductor substrate to pass through. In a cross section perpendicular to the second principal surface, the first bottom surface is longer than the first top surface, and the second bottom surface is shorter than the second top surface.

### CROSS-REFERENCE TO RELATED APPLICATIONS

This application is based upon and claims the benefit of priority from prior Japanese Patent Application No. 2011-136353, filed Jun. 20, 2011, the entire contents of which are incorporated herein by reference.

### FIELD

Embodiments described herein relate generally to a backside illumination solid-state image pickup device.

### BACKGROUND

In recent years, backside illumination solid-state image pickup devices have been researched. In a backside illumination solid-state image pickup device, signal processing circuits such as a logic circuit, an analog circuit, and a pixel scanning circuit is formed on a front surface side of a silicon substrate. A photoelectric conversion area and color filters, microlenses, and the like are formed on a back surface side of the silicon substrate.

Light delivered to the back surface of the silicon substrate is converted inside the silicon substrate in a photoelectric manner. The converted light is subjected to signal processing on the front surface side of the substrate. The processed light is then output. Scanning transistors and wires conventionally arranged in pixels are absent from the back surface side, thus allowing an aperture ratio of 100% to be achieved per pixel. Furthermore, the color filters and the microlenses can be reduced in profile, allowing light to be more properly condensed and reducing mixture of colors.

On the other hand, for alignment of the color filters and the microlenses, in a conventional solid-state image pickup device in which light is incident on the surface of the substrate, apertures through which light enters the substrate are defined by wires, and thus the color filters are formed in alignment with the wires. Since the wires are metal, even color filters for RGB, that is, red, green, and blue, for example, can be easily aligned with the wires.

However, the backside illumination solid-state image pickup device has the following problems.

The apertures through which light enters the silicon substrate are active areas partitioned by isolation layers formed on the front surface of the silicon substrate. The active area includes a photoelectric layer. Thus, to be aligned with the photoelectric layer, the position of the color filter needs to be aligned with a step of the isolation layer formed on the surface of the silicon substrate.

However, in the backside illumination solid-state image pickup device, the step needs to be detected across the thickness of the silicon substrate, which is 3 to 7 μm. Hence, the wavelength of a normal stepper fails to allow the color filter to be aligned with the isolation layer (or active area) on the surface of the silicon substrate. Thus, according to the conventional art, the color filter is aligned with the photoelectric layer by, for example, pre-forming a mark that penetrates the silicon substrate or cutting the silicon in the step portion of the isolation layer to expose the step.

However, the use of the mark penetrating the silicon substrate increases the number of steps required and results in indirect alignment with the isolation layer. Furthermore, the method of digging the silicon in the step portion of the isolation layer causes striation during the formation of the color filters. This makes acquisition of proper images difficult.

### BRIEF DESCRIPTION OF THE DRAWINGS

FIG. 1 is a cross-sectional view showing the structure of a solid-state image pickup device according to an embodiment;

FIG. 2A is a plan view of color filters in the solid-state image pickup device according to the embodiment;

FIG. 2B is a cross-sectional view taken along line 2B-2B in FIG. 2A;

FIG. 2C is a cross-sectional view taken along line 2C-2C in FIG. 2A;

FIG. 3A and FIG. 3B are cross-sectional views showing a method for manufacturing color filters in the solid-state image pickup device according to the embodiment;

FIG. 4A and FIG. 4B are plan views showing a method for manufacturing the color filters in the solid-state image pickup device according to the embodiment;

FIG. 4C is a cross-sectional view taken along line 4C-4C in FIG. 4A;

FIG. 4D is a cross-sectional view taken along line 4D-4D in FIG. 4B;

FIG. 5A and FIG. 5B are cross-sectional views showing a method for manufacturing color filters in the solid-state image pickup device according to the embodiment;

FIG. 6A and FIG. 6B are plan views showing a method for manufacturing the color filters in the solid-state image pickup device according to the embodiment;

FIG. 6C is a cross-sectional view taken along line 6C-6C in FIG. 6A;

FIG. 6D is a cross-sectional view taken along line 6D-6D in FIG. 6B;

FIG. 7A and FIG. 7B are cross-sectional views showing a method for manufacturing color filters in the solid-state image pickup device according to the embodiment;

FIG. 8A and FIG. 8B are plan views showing a method for manufacturing the color filters in the solid-state image pickup device according to the embodiment;

FIG. 8C is a cross-sectional view taken along line 8C-8C in FIG. 8A; and

FIG. 8D is a cross-sectional view taken along line 8D-8D in FIG. 8B.

### DETAILED DESCRIPTION

A solid-state image pickup device according to embodiments will be described with reference to the drawings. In the following description, components with the same functions and configurations are denoted by the same reference numerals, and duplicate descriptions are given only when needed.

In general, according to one embodiment, a solid-state image pickup device includes a semiconductor substrate, a first photoelectric conversion layer, a second photoelectric conversion layer, a circuit, a first color filter and a second color filter. The semiconductor substrate includes a first principal surface and a second principal surface lying opposite the first principal surface. The first photoelectric conversion layer and the second photoelectric conversion layer is formed both in the semiconductor substrate to convert incident light into an electric signal. The circuit is formed on the first principal surface to process the electric signals output by the first and second photoelectric conversion layers. The first color filter is arranged on the second principal surface to correspond to the first photoelectric conversion layer and includes a first bottom surface lying on the second principal surface side and a first top surface lying opposite the first bottom surface. The second color filter is arranged on the second principal surface to correspond to the second photoelectric conversion layer and includes a second bottom surface lying on the second principal surface side and a second top surface lying opposite the second bottom surface. The first color filter includes a spectroscopic filter configured to allow light having passed through the semiconductor substrate to pass through. In a cross section perpendicular to the second principal surface, the first bottom surface is longer than the first top surface, and the second bottom surface is shorter than the second top surface.

### First Embodiment

### [1] Structure of the Solid-State Image Pickup Device

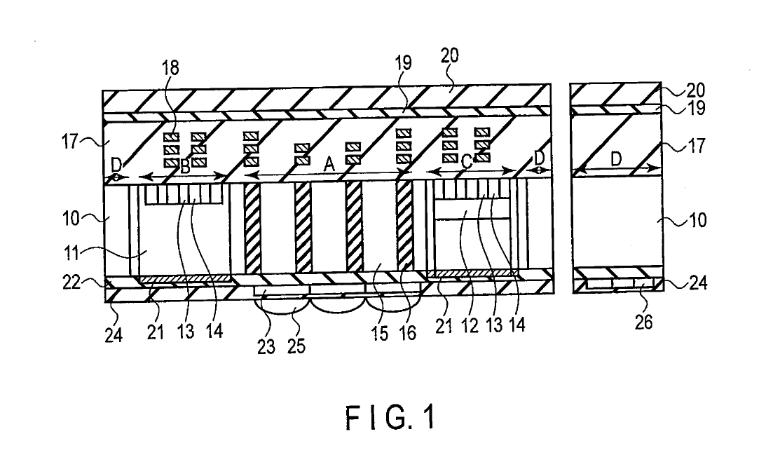

FIG. 1 is a cross-sectional view showing the structure of a solid-state image pickup device according to a first embodiment.

As shown in FIG. 1, a pixel area A, an analog area B, an analog area B, a logic area C, and a dicing line area D located at the terminal of a chip.

On a semiconductor substrate (for example, a silicon single-crystal substrate) 10 with an epitaxial layer, a P well layer 11 is formed in the analog area B, and an N well layer 12 is formed in the logic area C. For example, N channel transistors 13 and P channel transistors 14 are formed in each well layer. A first principal surface of the semiconductor substrate 10 on which the transistors 13 and 14 are formed is hereinafter referred to as a front surface. A principal surface of the semiconductor substrate 10 which lies opposite the front surface is hereinafter referred to as a back surface.

In the pixel area A, photoelectric conversion layers 15 and photoelectric conversion isolation layers 16 are formed; the photoelectric conversion layers 15 include photo diodes, and the photoelectric isolation layers 16 isolate the photoelectric layers 15 from one another.

An interlayer insulating film 17 and metal wires 18 are formed on the front surface of the semiconductor substrate 10, that is, on the transistors 13 and 14, on the photoelectric conversion layers 15, and on the photoelectric conversion isolation layers 16. The metal wires 18 are stacked in the interlayer insulating film 17 in layers via the insulating film.

On the interlayer insulating film 17, a support substrate 20 is formed via an adhesive layer 19. In other words, the interlayer insulating film 17 is joined to the support substrate 20 by the adhesive layer 19. Thus, the semiconductor substrate 10 is fixed by the support substrate 20.

The back surface of the semiconductor substrate 10 includes cut portions, and a metal sputter layer 21 is formed in the cut portions of the back surface of the semiconductor substrate 10, which portions correspond to the analog area B and logic area C. A flattening layer 22 is formed on the back surface of the semiconductor substrate 10 and on the metal sputter layer 21.

Color filters 23 are formed in the pixel area A on the flattening layer 22 to correspond to the respective photoelectric conversion layers 15. A protect layer 24 is formed on the flattening layer 22 and on the color filters 23. Moreover, microlenses 25 are formed on the protect layer 24 to correspond to the respective color filters 23.

The color filters 23 are formed of red color filters, green color filters, and blue color filters. The red color filter is hereinafter referred to as the red filter. The green color filter is hereinafter referred to as the green filter. The blue color filter is hereinafter referred to as the blue filter. The red filter allows red light to pass through. The green filter allows green light to pass through. The blue filter allows blue light to pass through. The structure of the color filters 23 will be described below in detail.

Light entering the microlens 25 passes through the microlens 25 and the corresponding color filter 23 into the corresponding photoelectric conversion layer 15. The photoelectric conversion layer 15 converts the incident light into an electric signal. Circuits formed in the analog area B and the logic area C process the electric signal output by the photoelectric conversion layer 15.

Furthermore, the dicing line area D at the terminal of the chip has the following structure.

The interlayer insulating film 17 is formed on the front surface of the semiconductor substrate 10. The support substrate 20 is formed on the interlayer insulting film 17 via the adhesive layer 19. Alignment marks 26 formed of color filters are provided on the back surface of the semiconductor substrate 10. The alignment marks 26 include a red filter mark formed of a red filter, a green filter mark formed of a green filter, and a blue filter mark formed of a blue filter.

Moreover, the protect layer 24 is formed on the back surface of the semiconductor substrate 10 and on the alignment mark 26.

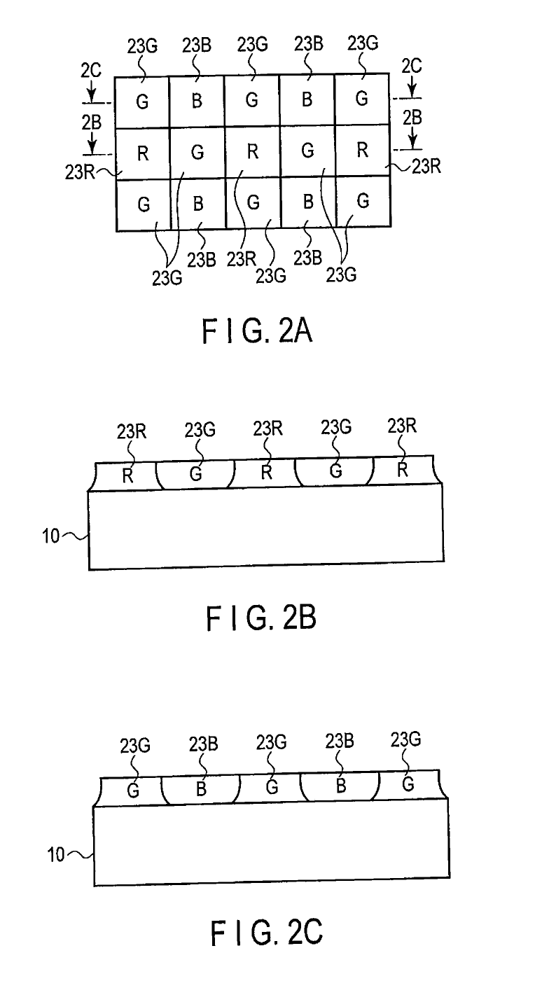

Now, the structure of the color filters 23 formed on the back surface of the semiconductor substrate 10 will be described with reference to FIG. 2A, FIG. 2B, and FIG. 2C.

FIG. 2A is a plan view of the color filters according to the embodiment. FIG. 2B is a cross-sectional view taken along line 2B-2B in FIG. 2A. FIG. 2C is a cross-sectional view taken along line 2C-2C in FIG. 2A.

As shown in the plan view in FIG. 2A, the red filters 23R, the green filters 23G, and the blue filters 23B are arranged in a matrix. Here, the arrangement is as shown in FIG. 2A. However, the present embodiment is not limited to this, and any other arrangement may be used. Furthermore, in FIGS. 2A, 2B, and 2C, the red filter is denoted as R, the green filter is denoted as G, and the blue filer is denoted as B. This also applies to the subsequent figures.

The sectional structure of the color filers is as follows.

As shown in FIG. 2B, the red filters 23R are arranged on the back surface of the semiconductor substrate 10, and the green filters 23G are each arranged between the red filters 23R. A side surface of the red filter 23R is in contact with a side surface of the green filter 23G. In the cross section shown in FIG. 2B, a bottom surface of the red filter 23R is longer than a top surface thereof. On the other hand, a bottom surface of the green filter 23G is shorter than a top surface thereof.

Furthermore, as shown in FIG. 2C, the green filters 23G are arranged on the back surface of the semiconductor substrate 10, and the blue filters 23B are each arranged between the green filters 23G. A side surface of the green filter 23G is in contact with a side surface of the blue filter 23B. In the cross section shown in FIG. 2C, a bottom surface of the green filter 23G is longer than a top surface thereof. On the other hand, a bottom surface of the blue filter 23B is shorter than a top surface thereof.

The above-described structure shown in FIG. 2B and FIG. 2C indicates that the red filters 23R have been formed earlier than the green filters 23G and that the green filters 23G have been formed earlier than the blue filters 23B. That is, the color filters 23 on the back surface of the semiconductor substrate 10 have been manufactured starting with the red filters 23R, followed by the green filters 23G and the blue filters 23B in that order. In this case, the green filters 23G are formed after the red filters 23R are formed. However, the present embodiment is not limited to this, and the blue filters 23B and the green filters 23G may be formed in that order after the red filters 23R are formed.

The first embodiment allows formation of color filters that are less misaligned with the photoelectric conversion layers including the photo diodes. This enables the reduction of mixture of colors resulting from the misalignment of the color filters, thus providing images with improved color reproducibility.

### [2] Method For Manufacturing a Solid-State Image Pickup Device

As a method for manufacturing a solid-state image pickup device, a method for manufacturing color filters that are a characteristic portion will be described below.

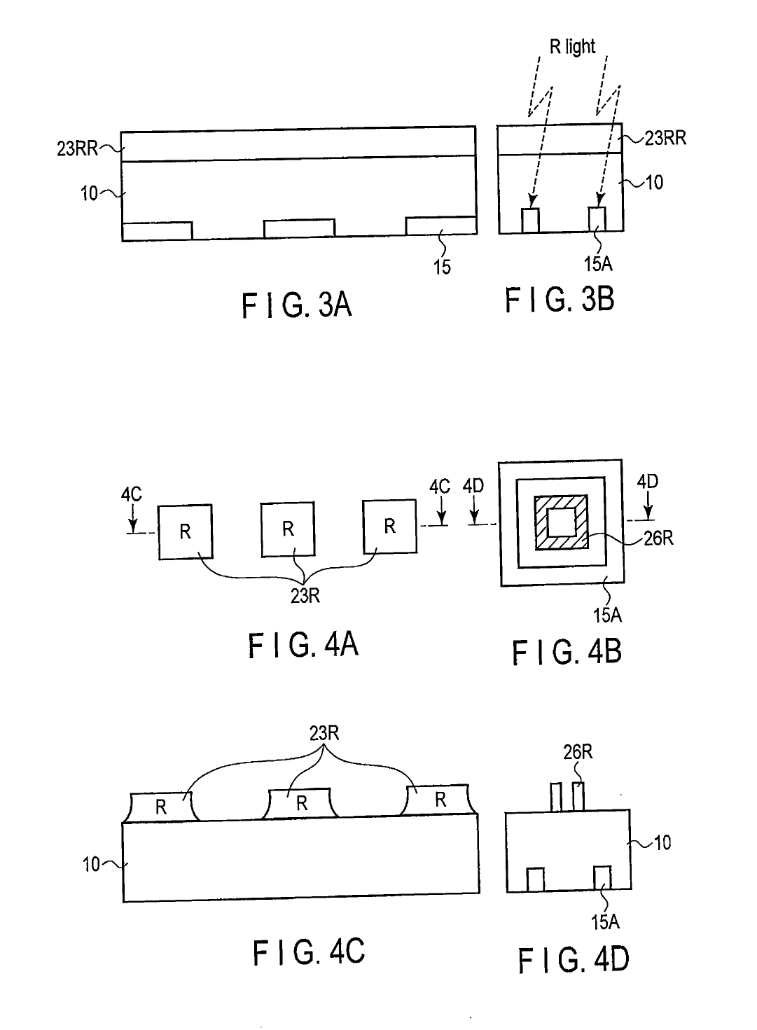

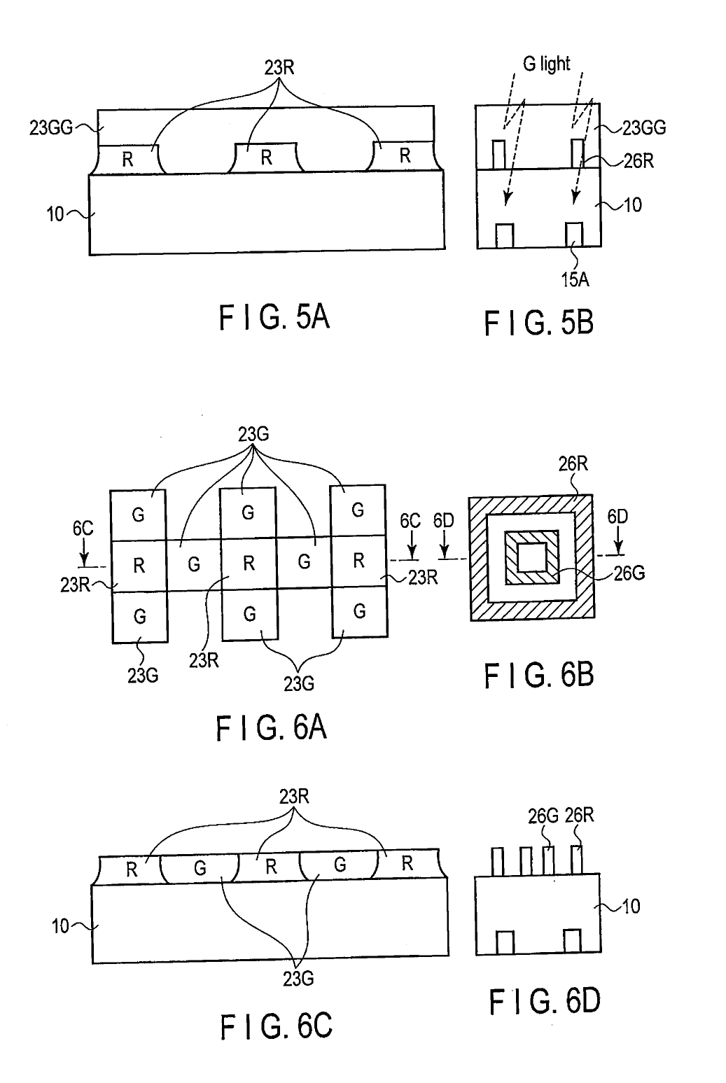

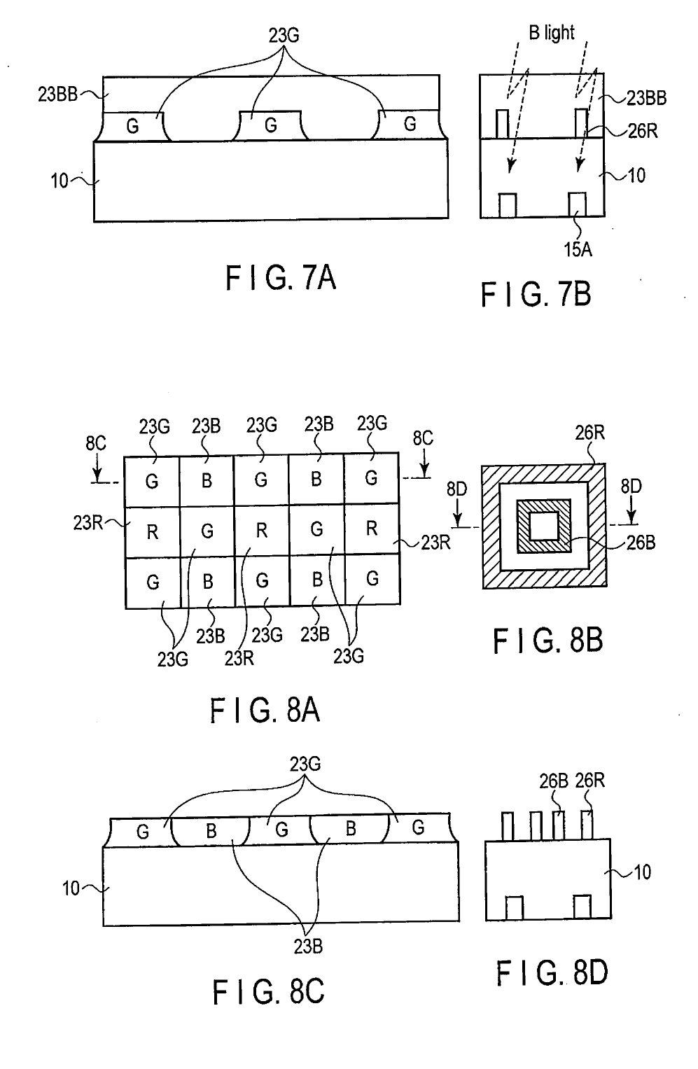

FIGS. 3A and 3B to FIGS. 8A, 8B, 8C, and 8D are diagrams showing a method for manufacturing the color filters in the solid-state image pickup device according to the first embodiment. FIG. 3A, FIG. 4C, FIG. 5A, FIG. 6C, FIG. 7A, and FIG. 8C are cross-sectional views of the area in which the color filters are formed. FIG. 4A, FIG. 6A, and FIG. 8A are plan views of the color filters. FIG. 3B, FIG. 4D, FIG. 5B, FIG. 6D, FIG. 7B, and FIG. 8D are cross-sectional views of the alignment mark formed in the dicing line area. FIG. 4B, FIG. 6B, and FIG. 8B are plan views of the alignment mark. The three alignment marks, that is, the alignment mark shown in FIG. 3B, FIG. 4B, and FIG. 4D, the alignment mark shown in FIG. 5B, FIG. 6B, and FIG. 6D, and the alignment mark shown in FIG. 7B, FIG. 8B, and FIG. 8D are not the identical alignment mark formed at the same place but are formed in different places.

First, as shown in FIG. 3A and FIG. 3B, a film 23RR serving as red filters is formed all over the back surface of the semiconductor substrate 10 with the photoelectric conversion layers 15. Subsequently, the film 23RR is exposed and developed by a lithography method to form red filers 23R on the back surface of the semiconductor substrate 10 as shown in FIG. 4A to FIG. 4D. At this time, the red filters 23R are formed in alignment with the positions of the photoelectric conversion layers 15 formed on the semiconductor substrate 10 and including the photo diodes. That is, the positions of the red filters 23R are determined by carrying out the exposure using, as a reference for alignment, an active area 15A formed as an alignment mark in the dicing line area. The active area 15A is formed during the same step as that for the photoelectric conversion layers 15.

Moreover, simultaneously with the formation of the red filters 23R in alignment with the active area 15A, the film 23RR, serving as the red filters, is patterned to form a red filter mark 26R as shown in FIG. 4B and FIG. 4D. Furthermore, a red filter mark 26R is formed in another place in the dicing line area as shown in FIG. 5B and FIG. 7B.

In the step of forming the red filters 23R, light with a long wavelength such as red (R light) is used for alignment. This enables the active area 15A on the front surface side of the semiconductor substrate 10 to be detected, allowing the red filters 23R to be aligned with the active area 15A. Although the red light passes through the semiconductor substrate 10 and enables the active area 15A on the front surface side of the semiconductor substrate 10 to be detected, light with a short wavelength such as green or blue fails to allow the active area 15A on the front surface side of the semiconductor substrate 10 to be detected.

Then, as shown in FIG. 5A and FIG. 5B, a film 23GG serving as green filters is formed all over the back surface of the semiconductor substrate 10. Subsequently, the film 23GG is exposed and developed by the lithography method to form green filers 23G on the back surface of the semiconductor substrate 10 as shown in FIG. 6A to FIG. 6D. At this time, the green filters 23G are formed in alignment with the positions of the red filters 23R formed on the semiconductor substrate 10. That is, the positions of the green filters 23G are determined by carrying out the exposure using, as a reference for alignment, a red filter mark 26R formed as an alignment mark in the dicing line area.

Moreover, simultaneously with the formation of the green filters 23G in alignment with the red filters 23R, the film 23GG, serving as the green filters, is patterned to form a green filter mark 26G as shown in FIG. 6B and FIG. 6D.

In the step of forming the green filters 23G, light with a short wavelength such as green (G light) is used. This precludes the active area 15A on the front surface side of the semiconductor substrate 10 from being detected. Thus, the green filters 23G are formed in alignment with the red filter mark 26R formed on the back surface of the semiconductor substrate 10.

Then, as shown in FIG. 7A and FIG. 7B, a film 23BB serving as green filters is formed all over the back surface of the semiconductor substrate 10. Subsequently, the film 23BB is exposed and developed by the lithography method to form blue filers 23B on the back surface of the semiconductor substrate 10 as shown in FIG. 8A to FIG. 8D. At this time, the blue filters 23B are formed in alignment with the positions of the red filters 23R formed on the semiconductor substrate 10. That is, the positions of the blue filters 23B are determined by carrying out the exposure using, as a reference for alignment, the red filter mark 26R formed as an alignment mark in the dicing line area.

Moreover, simultaneously with the formation of the blue filters 23B in alignment with the red filters 23R, the film 23BB, serving as the blue filters, is patterned to form a blue filter mark 26B as shown in FIG. BB and FIG. 8D.

In the step of forming the blue filters 23B, light with a short wavelength such as blue (B light) is used. This precludes the active area 15A on the front surface side of the semiconductor substrate 10 from being detected. Thus, the blue filters 23B are formed in alignment with the red filter mark 26R formed on the back surface of the semiconductor substrate 10.

Subsequently, the microlenses 25 are formed, as shown in FIG. 1, in alignment with the positions of the red filters 23R formed on the back surface of the semiconductor substrate 10. That is, the positions of the microlenses 25 are determined using, as a reference for alignment, the red filter mark 26R formed in the dicing line area as an alignment mark.

According to the present embodiment, when a plurality of color filters are formed, the red filter, allowing the red light, which has a long wavelength, to pass through, is the first to be formed. This enables the active area positioned deeper than the interface at the back surface to be detected. Thus, the positions of the color filters can be aligned with the active area including a photo diode.

Furthermore, the above-described method for manufacturing eliminates the need to form a dedicated mark on the back surface of the semiconductor substrate. For example, no trench needs to be formed in the back surface of the semiconductor substrate or the silicon substrate need not be dug in the area in which the active area is formed. Thus, even in the backside illumination solid-state image pickup device, the color filters can be accurately aligned with the active area including the photo diode, without any increase in the number of steps required.

### Second Embodiment

According to a second embodiment, red filters are formed, and blue filters are then formed in alignment with the red filters. Finally, green filters are formed in alignment with the red filters. Moreover, each of the red and blue filters is about 80 or 90% of the green filter in area. That is, the green filter is slightly larger than each of the red and green filters in area. The manufacturing steps according to the first embodiment may be used for the second embodiment, for example, by interchanging the orders of the step of forming the green filters and the step of forming the blue filters.

The present embodiment sets the green filter larger than each of the red and blue filters in area. Thus, the green filters allow the transmission of light that most affects a photosensitivity characteristic, thus enabling the photosensitivity characteristic of the photoelectric conversion layers to be improved. The other configurations and effects are similar to those in the first embodiment.

According to the present embodiment, the green filers are formed before the blue filters are formed. However, the following procedure is possible: after the red filters are formed, the green filters are formed to be larger than the red filters by 10 or 20 percents, and then the blue filters are formed. This formation procedure also allows the photosensitivity characteristic of the photoelectric conversion layers to be similarly improved.

As described above, the embodiments can form color filters and microlenses with reduced misalignment with respect to photo diodes without the need for a special step exclusive to the backside illumination solid-state image pickup device or formation of a mark also exclusive to the backside illumination solid-state image pickup device. This enables the reduction of mixture of colors resulting from the misalignment of the color filters, thus providing images with improved color reproducibility.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state image pickup device comprising:
a semiconductor substrate comprising a first principal surface and a second principal surface lying opposite the first principal surface;
a first photoelectric conversion layer and a second photoelectric conversion layer both formed in the semiconductor substrate to convert incident light into an electric signal;
a circuit formed on the first principal surface to process the electric signals output by the first and second photoelectric conversion layers;
a first color filter arranged on the second principal surface to correspond to the first photoelectric conversion layer and comprising a first bottom surface lying on the second principal surface side and a first top surface lying opposite the first bottom surface; and
a second color filter arranged on the second principal surface to correspond to the second photoelectric conversion layer and comprising a second bottom surface lying on the second principal surface side and a second top surface lying opposite the second bottom surface,
wherein the first color filter includes a spectroscopic filter configured to allow light having passed through the semiconductor substrate to pass through, and
in a cross section perpendicular to the second principal surface, the first bottom surface is longer than the first top surface, and the second bottom surface is shorter than the second top surface.

2. The solid-state image pickup device according to claim 1, wherein the first color filter includes a filter configured to allow red light to pass through.

3. The solid-state image pickup device according to claim 1, wherein the second color filter includes a filter configured to allow light most affecting a photosensitivity characteristic to pass through.

4. The solid-state image pickup device according to claim 3, wherein the second color filter includes a filter configured to allow green light to pass through.

5. The solid-state image pickup device according to claim 3, wherein the second color filter is larger than the first color filter in area.

6. The solid-state image pickup device according to claim 1, further comprising a third photoelectric conversion layer formed in the semiconductor substrate to convert incident light into an electric signal; and
a third color filter arranged on the second principal surface to correspond to the third photoelectric conversion layer and adjacent to the first and second color filters, the third color filter comprising a third bottom surface lying on the second principal surface side and a third top surface lying opposite the third bottom surface.

7. The solid-state image pickup device according to claim 6, wherein in a cross section perpendicular to the second principal surface, the third bottom surface is shorter than the third top surface.

8. The solid-state image pickup device according to claim 6, wherein the second color filter is larger than the third color filter in area.

9. The solid-state image pickup device according to claim 6, further comprising:
microlenses arranged to correspond to the first, second, and third color filters, respectively.

10. A method for manufacturing a solid-state image pickup device comprising:
forming, on a first principal surface of a semiconductor substrate with a photoelectric conversion layer configured to convert incident light into an electric signal, a circuit configured to process the electric signal output by the photoelectric conversion layer;
forming a first color filter on a second principal surface of the semiconductor substrate which lies opposite the first principal surface, in alignment with a position of the photoelectric conversion layer, and forming a first alignment mark on the second principal surface; and
forming a second color filter and a second alignment mark on the second principal surface using the first alignment mark for alignment;
wherein in the formation of the first color filter and the first alignment mark, the first color filter is aligned with the photoelectric conversion layer using light that passes through the first color filter and the semiconductor substrate.

11. The method for manufacturing a solid-state image pickup device according to claim 10, wherein the first color filter includes a spectroscopic filter configured to allow transmission of light with a wavelength longer than a wavelength transmitted through the second color filter.

12. The method for manufacturing a solid-state image pickup device according to claim 10, wherein the first color filter includes a spectroscopic filter configured to allow transmission of red light that passes through the semiconductor substrate, and the second color filter includes a spectroscopic filter configured to allow green or blue light to pass through.

13. The method for manufacturing a solid-state image pickup device according to claim 10, further comprising forming a third color filter and a third alignment mark on the second principal surface using the first alignment mark for alignment.

14. The method for manufacturing a solid-state image pickup device according to claim 13, wherein the first color filter includes a spectroscopic filter configured to allow transmission of light with a wavelength longer than wavelengths transmitted through the second and third color filters.

15. The method for manufacturing a solid-state image pickup device according to claim 13, wherein the first color filter includes a spectroscopic filter configured to allow transmission of red light that passes through the semiconductor substrate, the second color filter includes a spectroscopic filter configured to allow green light to pass through, and the third color filter includes a spectroscopic filter configured to allow blue light to pass through.
